(19) United States
(12) Patent Application Publication
(10) Pub. No.: US 2017/0238446 A1
(43) Pub. Date: Aug. 17, 2017

(54) DISPLAY PANEL AND DISPLAY DEVICE

(71) Applicant: BOE TECHNOLOGY GROUP CO., LTD., Beijing (CN)

(72) Inventor: Yanbing WU, Beijing (CN)

(21) Appl. No.: 15/502,431

(22) PCT Filed: Jun. 16, 2015
(86) PCT No.: PCT/CN2015/081572

§ 371 Date: Feb. 7, 2017

(30) Foreign Application Priority Data
Jan. 22, 2015 (CN) 201510033159.8

(51) Int. Cl. H05K 7/20; H01L 23/00; H01L 23/367; H01L 23/373

(52) U.S. Cl. CPC H05K 7/20963; H01L 23/3736; H01L 24/32; H01L 23/3675; H01L 2224/32245; H01L 2924/1426

(57) ABSTRACT

A display panel and a display device are provided. The display panel includes a substrate (1) and a frame (2). The substrate (1) is provided with a display area (11) and a non-display area (12). The non-display area (12) is provided with a chip (3) and a heat dissipation layer (4) that is made of a thermal conductive material, the surface (42) of the heat dissipation layer (4) not connecting with the substrate includes two parts, one part is connected with the chip (3), and the other part is connected with the frame (2). The display panel can be applied in a display device, and the display panel can solve the heat dissipation problem which occurs when the chip is integrated into the display panel.

### TECHNICAL FIELD

Embodiments of the present disclosure relate to a display panel and a display device.

### BACKGROUND

In general, a driver chip of a display panel is arranged in the form as shown in FIG. 1, and the display panel includes a substrate 01, the substrate 01 includes a display area 011 and a non-display area 012, and a small power driver chip 02 is usually arranged in the non-display area 012, then the small power driver chip is connected, through a flexible circuit board 03, with a printed circuit board 04; however, a high power chip 05 is usually arranged on the printed circuit board 04.

However, in order to make the frame of the display panel narrower, integrating more chips into the display panel has become an inevitable trend. In general, the reason why there is no high power chip arranged on the substrate is that the substrate is made of glass, and the thermal conductivity of glass is not good. Therefore, if the high power chip is arranged on the glass substrate, the problem of poor heat dissipation occurs, and then the chip will be damaged.

### SUMMARY

According to embodiments of the present disclosure, a display panel and a display device are provided. A chip can be integrated into the display panel, and the problem of poor heat dissipation involving the chip can be solved.

According to an embodiment of the present disclosure, a display panel is provided, and the display panel includes a substrate and a frame, the substrate is provided with a display area and a non-display area, the non-display area is provided with a chip and a heat dissipation layer that is made of a thermal conductive material, the surface of the heat dissipation layer not contacting with the substrate includes two parts, one part is connected with the chip, and the other part is connected with the frame.

For example, in the display panel, the chip is integrally arranged on the surface of the heat dissipation layer.

For example, the display panel further includes a heat conductive adhesive, the chip is connected with the heat dissipation layer through the heat conductive adhesive, and the heat dissipation layer is connected with the frame through the heat conductive adhesive.

For example, in the display panel, the heat dissipation layer is made of a metal material.

For example, in the display panel, the heat dissipation layer is made of copper.

For example, in the display panel, an area of the non-display area not provided with the chip is a free surface, and the heat dissipation layer covers the free surface of the non-display area.

For example, in the display panel, an area of the non-display area used for setting the chip includes a wire connection region and a chip covering area, the wire connection area is used for setting the wires of the chip, and the part connecting the heat dissipation layer and the chip is located in the chip covering area.

According to an embodiment of the present disclosure, a display device is provided, and the display device includes any one of the display panels of the above-mentioned technical solutions.

### BRIEF DESCRIPTION OF THE DRAWINGS

In order to clearly illustrate the technical solution of the embodiments of the disclosure, the drawings of the embodiments will be briefly described in the following, it is obvious that the described drawings are only related to some embodiments of the disclosure and thus are not limitative of the disclosure.

FIG. 1 is a structure schematic diagram of a display panel;

FIG. 2 is a structure schematic diagram of a display panel provided by and embodiment of the present disclosure;

FIG. 3 is a structure schematic diagram of a display panel using a heat conductive adhesive to connect a chip with a heat dissipation layer provided by an embodiment of the present disclosure; and

FIG. 4 is a distribution schematic diagram of a wire connection area and a chip covering area of a display panel provided by an embodiment of the present disclosure.

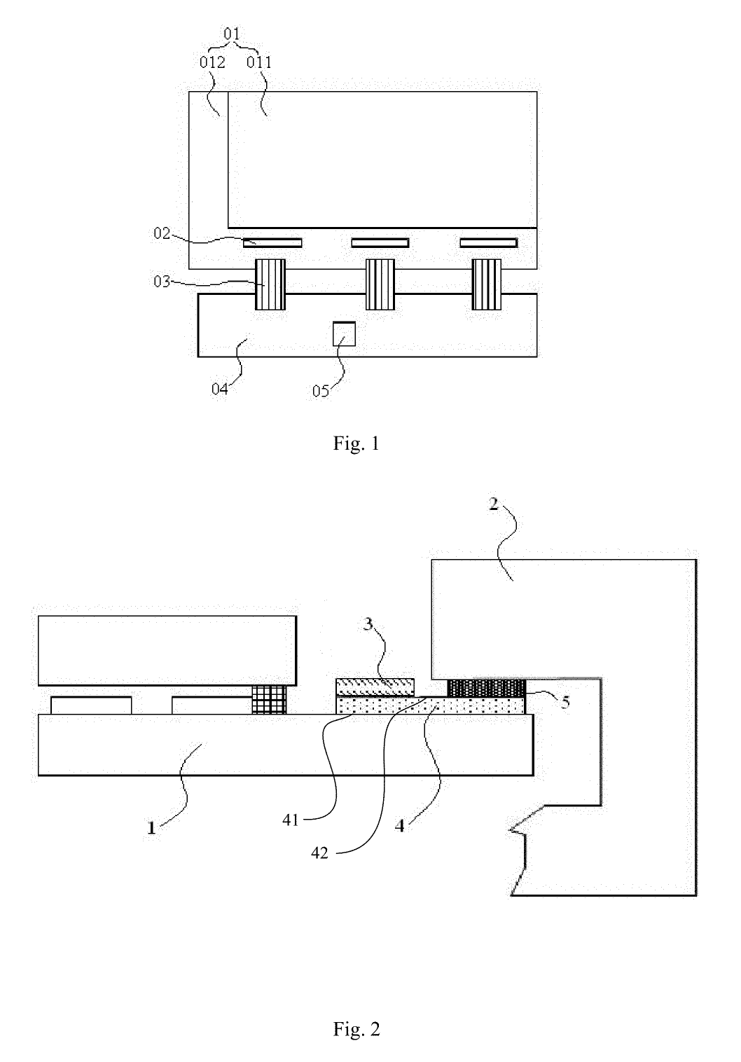

### REFERENCE NUMERALS

1—substrate, 2—frame, 3—chip, 4—heat dissipation layer, 41—surface of heat dissipation layer contacting with substrate, 42—surface of heat dissipation layer not contacting with substrate, 5—heat conductive adhesive, 11—display area, 12—non-display area, 121—wire connection area, 122—chip covering area, 123—free surface.

### DETAILED DESCRIPTION

The technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

In the description of the embodiments of the present disclosure, it should be understood that the orientation or position relationships indicated by the terms such as “center,” “up,” “down,” “before,” “after,” “left,” “right,” “vertical,” “horizontal,” “top,” “bottom,” “inside,” “outside,” etc. are the orientation or position relationships based on the drawings, which are only used to facilitate the description of the present disclosure or simplify the description, and are not intended to indicate or suggest that the devices or components should have the specific orientations, or should be manufactured and operated in the specific positions. Therefore, the terms cannot be understood as the limitations of the present disclosure.

In the description of the embodiments of the present disclosure, it's to be noted that the terms “installation,” “connected,” “connection,” etc. should be understood in a broad sense unless otherwise specified and defined. For example, the term “connection” may be a fixed connection, may be a detachable connection or an integrated connection; may be a mechanical connection, or an electrical connection; may be direct connection, or indirect connection through an intermediate media, or may involve internal connection of two components. For those skilled in the art, the specific meanings of the terms can be understood in particular cases in the embodiments of the present disclosure.

FIG. 2 and FIG. 4 illustrate a specific example of a display panel provided by an embodiment of the present disclosure. Referring to FIG. 2 and FIG. 4, the display panel of the present disclosure includes a substrate 1 and a frame 2. The substrate 1 is provided with a display area 11 and a non-display area 12. The non-display area 12 is provided with a heat dissipation layer 4 that is made of a thermal conductive material, the surface of the heat dissipation layer 4 not contacting with the substrate includes two parts, one part is connected with the chip 3, and the other part is connected with the frame 2.

It should be noted that the heat dissipation layer 4 includes a surface contacting with the substrate 41 and a surface not contacting with the substrate 42. The surface of the heat dissipation layer 4 not contacting with the substrate includes at least two parts, for example, the surface of the heat dissipation layer 4 not contacting with the substrate includes a part connecting with the chip 3 and a part connecting with the frame 2.

In the display panel provided by the embodiment of the present disclosure, the non-display area 12 of the substrate 1 is provided with a heat dissipation layer 4 that is made of a thermal conductive material, then the chip 3 is arranged on the heat dissipation layer 4, and a part of the heat dissipation layer 4 is connected with the frame 2. As a result, the heat generated by the chip 3 can be transmitted to the frame 2 through the heat dissipation layer 4. Both the heat dissipation layer 4 and the frame 2 can play a role of dissipating heat. Therefore, the problem of poor heat dissipation of the chip 3 occurring when the chip is integrated into the display panel can be solved.

For example, the heat dissipation layer 4 is connected with a portion of the chip 3 to achieve thermal conductivity. However, in order to make the contact area between the chip 3 and the heat dissipation layer 4 larger, as shown in FIG. 2, the chip 3 may be entirely arranged on the surface of the heat dissipation layer 4. As a result, the contacting area between the chip 3 and the heat dissipation layer 4 can reach the maximum value, which makes the heat dissipation effect of the chip 3 better.

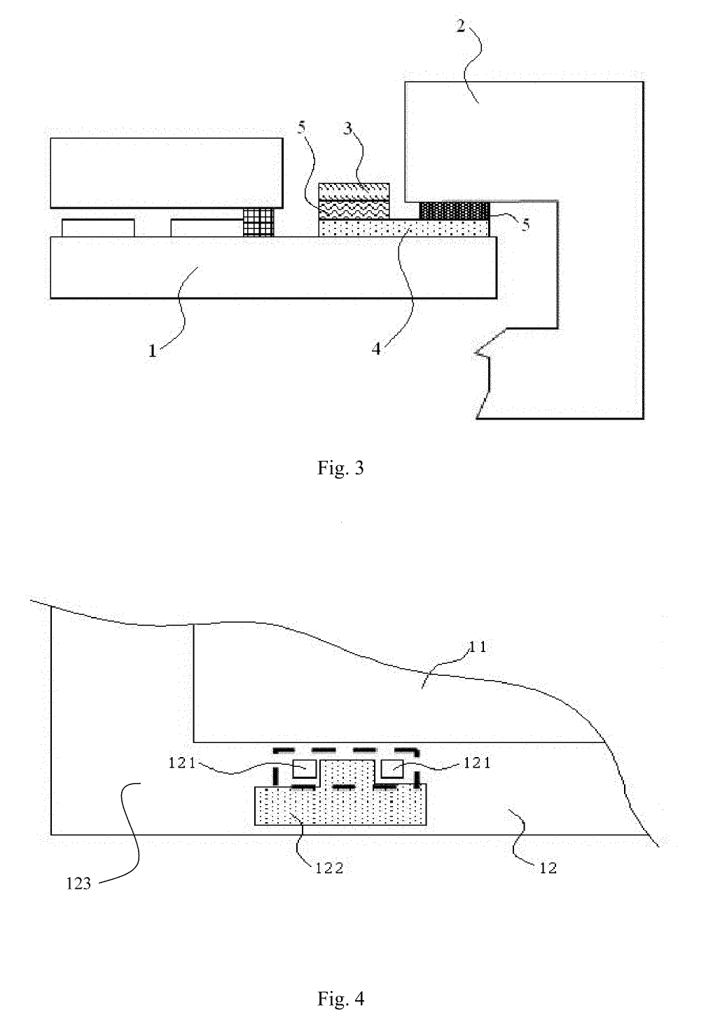

In order to connect the chip 3 and the heat dissipation layer 4, the methods such as bonding, welding or riveting etc. can be used. In order to avoid damages to the chip 3, the method of bonding can be adopted. At the same time, in order to ensure that good thermal conductivity between the chip 3 and the heat dissipation layer 4 after bonding, as shown in FIG. 3, the heat conductive adhesive 5 can be used to bond the chip 3 and the heat dissipation layer 4, and to bond the heat dissipation layer 4 and the frame 2 of the display panel.

The heat conductive adhesive is also known as thermal conductive silicone, which is a kind of silicone adhesive formed by the following steps: adding polymer materials such as a filling material and a heat conductivity material to the matrix of organic silicone, then mixing the materials. The adhesive has good thermal conductivity and a property of electrical insulation, and it is widely used in electronic components. Therefore, the heat conductive adhesive 5 can conduct heat and can also play a function of connecting, so good thermal conductivity can be ensured between the chip 3 and the heat dissipation layer 4 after the chip 3 and the heat dissipation layer 4 are bonded together.

In order to achieve a better heat dissipation effect and a better heat conductive effect of the heat dissipation layer 4, the heat dissipation layer 4 can be made of the materials with high heat conductivity coefficient. Therefore, metal materials can be used to prepare the heat dissipation layer 4. The thermal conductivity of copper is higher than that of the other metals among the commonly used metal materials, copper has better plasticity, and copper is more easily to be processed. Therefore, copper can be used to manufacture the heat dissipation layer 4.

The non-display area 12 of the substrate 1 is generally arranged around the display area 11, the non-display area 12 is provided with a chip 3 and a circuit, and the rest part of the non-display area 12 is a free surface. In order to make the heat dissipation layer 4 achieve a better effect of heat dissipation and a better effect of heat conduction, the heat dissipation layer 4 needs to occupy the free surface as much as possible. Therefore, the heat dissipation layer 4 may completely cover the free surface of the non-display area 12, as a result, the area of the heat dissipation layer 4 reaches the maximum value, and the effect of heat dissipation and heat conduction become better.

As shown in FIG. 4, the area in non-display area 12 used for setting the chip 3 includes a wire connection area 121 and a chip covering area 122. The wire connection area 121 is used for setting the wires of the chip 3, and the chip covering area 122 is an area covered by the main body of the chip 3. In order to avoid the influence of the metal heat dissipation layer 4 on the wire of the chip 3, the heat dissipation layer 4 may not be arranged in the wire connection area 121. That is, the connecting part of the heat dissipation layer 4 and the chip 3 is located in the chip covering area.

In the above embodiment, as the heat dissipation problem of the chip 3 can be solved, the chip 3 can be a high power chip, and the high power chip includes a continuous control chip, a system chip, a power conversion chip etc.

An embodiment of the present disclosure further provides a display device, and the display device includes the display panel includes any one of the display panels applying the above-mentioned technical solutions. For example, the display device can be: a liquid crystal panel, an electronic paper, an organic light-emitting diode (short for OLED), a mobile phone, a watch, a tablet computer, a television, a display, a notebook computer, a digital picture frame, a navigation system and any other product or component having a display function.

Because the display panel used in the display device in the present embodiment is the same as the display panel provided by each of the above-mentioned embodiments, both the display device and the display panel can solve the same technical problem, and can achieve the same expected effect.

The display panel and the display device provided by the embodiments of the present disclosure, the non-display area of the substrate is provided with the heat dissipation layer made of a thermal conductive material, then the chip is arranged on the heat dissipation layer, and a portion of the heat dissipation layer is connected with the frame. As a result, the heat generated by the chip can be transmitted to the frame through the heat dissipation layer. Both the heat dissipation layer and the frame can play a role of dissipating heat. Therefore, the problem of poor heat dissipation of the chip 3 occurring when the chip is integrated into the display panel can be solved.

The remaining structure of the display device in the embodiment of the present disclosure may be implemented with the structure well known for those skilled in the related art, which will not be described in detail herein for simplicity.

In the description of the above-mentioned embodiments, the specific characteristics, structures, materials or features can be combined in appropriate ways in any one or more of the embodiments or examples.

What are described above is related to the illustrative embodiments of the disclosure only and not limitative to the scope of the disclosure; any modifications and variations are easy for those skilled in the art to envisage in the technology scope disclosed by the present disclosure belong to the scope of the present disclosure. Therefore, the scopes of the disclosure are defined by the claims.

The present application claims the priority of the Chinese Patent Application No. 201510033159.8 filed on Jan. 22, 2015, the entirety of which is incorporated herein by reference as a part of the present application.

1. A display panel, comprising: a substrate and a frame, wherein the substrate is provided with a display area and a non-display area, the non-display area is provided with a chip and a heat dissipation layer that is made of a thermal conductive material, the surface of the heat dissipation layer not contacting with the substrate comprises two parts, one part is connected with the chip, and the other part is connected with the frame.

2. The display panel according to claim 1, wherein the chip is entirely arranged on the surface of the heat dissipation layer.

3. The display panel according to claim 2, further comprises a heat conductive adhesive, wherein the chip is connected with the heat dissipation layer through the heat conductive adhesive, and the heat dissipation layer is connected with the frame through the heat conductive adhesive.

4. The display panel according to claim 1, wherein the heat dissipation layer is made of a metal material.

5. The display panel according to claim 4, wherein the heat dissipation layer is made of copper.

6. The display panel according to claim 1, wherein an area of the non-display area not provided with the chip is a free surface, and the heat dissipation layer covers the free surface of the non-display area.

7. The display panel according to claim 1, wherein an area of the non-display area used for setting the chip comprises a wire connection region and a chip covering area, the wire connection area is used for setting the wires of the chip, and the part connecting the heat dissipation layer and the chip is located in the chip covering area.

8. A display device, comprising the display panel according to claim 1.

9. The display panel according to claim 2, wherein the heat dissipation layer is made of a metal material.

10. The display panel according to claim 9, wherein the heat dissipation layer is made of copper.

11. The display panel according to claim 3, wherein the heat dissipation layer is made of a metal material.

12. The display panel according to claim 11, wherein the heat dissipation layer is made of copper.
